(19) United States
(12) Patent Application Publication
(10) Pub. No.: US 2024/0418780 A1
(43) Pub. Date: Dec. 19, 2024

(54) Method for Measuring the Magnetic Saturation Profiles of a Synchronous Machine, and Device for the Open-Loop and Closed-Loop Control of an Induction Machine

(71) Applicant: KOSTAL Drives Technology GmbH, Luedenscheid (DE)

(72) Inventors: Peter Landsmann, Muenchen (DE); Dirk Paulus, Muenchen (DE); Sascha Kuehl, Muenchen (DE)

(73) Assignee: KOSTAL Drives Technology GmbH, Luedenscheid (DE)

(21) Appl. No.: 18/814,748

(22) Filed: Aug. 26, 2024

Related U.S. Application Data
(63) Continuation of application No. PCT/EP2022/055106, filed on Mar. 1, 2022.

(51) Int. Cl. G01R 31/34; H02P 23/14

(52) U.S. Cl. CPC G01R 31/343; H02P 23/14

(57) ABSTRACT

A method for measuring magnetic saturation profiles of a synchronous machine having a rotor and a stator includes actuating the synchronous machine with clocked terminal voltages according to a pulse width modulation process. The method further includes cyclically measuring a current of the synchronous machine resulting from the synchronous machine being actuated by the clocked terminal voltages. The method further includes applying macroscopic flux pulses which allow the current to momentarily increase into a range that can change a magnetic saturation state of the synchronous machine.

### CROSS-REFERENCE TO RELATED APPLICATIONS

This application is a continuation of International Application No. PCT/EP2022/055106, published in German, with an international filing date of Mar. 1, 2022, the disclosure of which is incorporated by reference herein.

### TECHNICAL FIELD

The present invention relates to a method for measuring the magnetic saturation profiles of a synchronous machine having a rotor and a stator, wherein the synchronous machine is activated by clocked terminal voltages according to the pulse width modulation process, and the current of the synchronous machine is measured cyclically. The present invention further relates to a device for the open-loop and closed-loop control of an induction machine.

The method and device are used, when putting a synchronous motor into service, to derive rotor position assignment parameters to allow the motor to be controlled without position sensors.

### BACKGROUND

The now well-established high-performance and high-efficiency control of synchronous machines is based on knowledge of the rotor position signal. So-called rotor position feedback allows the use of efficiency- and power-optimized motor control methods, as well as the fulfillment of higher-order tasks such as rotational speed control or positioning. The measurement of the rotor position generally takes place during operation by use of a sensor that is mounted at the rotor shaft, the so-called rotor position sensor or “sensor” for short.

Sensors have several disadvantages, for example increased system costs, reduced robustness, increased likelihood of failure, and large installation space requirements, which has prompted interest by major industries in obtaining the position signal without use of a sensor.

Methods that allow this are referred to as “sensor-less” closed-loop control, and are divided into two classes:
1. Fundamental wave methods evaluate the voltage induced by movement. At average and high rotational speeds, they provide very good signal properties, but they fail in the lower rotational speed range, particularly when the machine is at a standstill.
2. Anisotropy methods evaluate the position dependency of the inductance of the machine, which is possible even at low rotational speeds or at a standstill.

The term “machine” is used here in the sense of an electric machine, i.e., an electric motor or an electric generator. The terms “machine,” “motor,” and “generator” are synonymous regarding the presented method, so that they may be used interchangeably.

To assign rotor position values to the fundamental wave and the anisotropy, certain motor parameters are necessary in each case. This drawback compared to sensors becomes greater as the time-consumption and complexity of the parameter determination increases. Automated self-commissioning of all required parameters thus contributes significantly to the applicability of a sensor-less method.

Although the unambiguous (unique) rotor position assignment for anisotropy and for fundamental waves has made considerable progress in sensor-less control regarding the general operating behavior and especially regarding the load stability, both approaches require complex sets of parameters. This is because the profiles (curves) of flux and/or inductance/admittance are necessary when large currents are applied (the same overload factor as during operation), in which correspondingly large torques arise. Therefore, the parameter determination has thus far required a load test stand, in which a load machine supports the torque that arises during the parameter measurement.

In the present context, the term “flux ψ” herein refers to the magnetic flux linkage Ψ minus its remanence component. For zero current, by definition, the flux ψ is also zero, while the entire magnetic flux linkage Ψ for permanent magnet (PM) motors, for example, still contains an offset ψₚₘ. In conjunction with the flux, the term “pulse” herein refers to the briefest possible application of a certain flux value, and the term “macroscopic” herein refers to the magnitude of the flux value: namely, that the flux pulses are to bring about current values over the entire operating range of the motor, which may be a function of the application of a multiple of the nominal (rated) motor current, and which generally result in a change in the magnetic saturation state of the motor. On the other hand, there are “microscopic” flux pulses which are applied, for example, when anisotropy processes are used. These are preferably kept small, and do not seek to change the saturation state.

### SUMMARY

Embodiments of the present invention relate to a method for measuring the magnetic saturation profiles of a synchronous machine having a rotor and a stator. The synchronous machine is activated by clocked terminal voltages according to a pulse width modulation process and the current of the synchronous machine is measured cyclically. Embodiments of the present invention also relate to a device for the open-loop and closed-loop control of an induction machine. The method and device described are used, when putting a synchronous motor into service, to derive motor position allocation parameters to allow the motor to be controlled without a position sensor.

A method for measuring magnetic saturation profiles of a synchronous machine having a rotor and a stator is provided. The method includes actuating the synchronous machine with clocked terminal voltages according to a pulse width modulation process. The method further includes cyclically measuring a current of the synchronous machine resulting from the synchronous machine being actuated by the clocked terminal voltages. The method further includes applying macroscopic flux pulses which allow the current to momentarily increase into a range that can change a magnetic saturation state of the synchronous machine.

The presented method in accordance with embodiments of the present invention determines a set of parameters for unambiguous rotor position assignment without use of a load test stand, i.e., solely by connection of the converter to the synchronous machine. Macroscopic flux pulses are applied (impressed) which generate the brief magnetic saturation states, the same as those occurring during operation. This results in corresponding current and torque values, which, however, due to the short duration (short time-period) of the pulse application (impression) do not change the rotational speed, and thus also the rotor position, greatly enough to have a relevant effect on obtaining the parameters. In one embodiment, when the saturation state is reached, an injection cycle is additionally run through to also obtain the admittance/inductance values at this operating point.

### BRIEF DESCRIPTION OF THE DRAWINGS

A general explanation, also concerning optional embodiments of the present invention, is provided below. In the Figures:

FIG. 1 shows a time curve (plot) of voltage u (top graph), resulting flux v (middle graph), and current i (bottom graph), in each case with a d-component (solid line) and a q-component (dashed line) during a macroscopic flux pulse.

FIG. 2 shows an illustration of the current responses of all flux pulses of an initial start-up operation, plotted in normalized dq coordinates (based on the nominal motor current), the flux pulse values being equidistantly distributed, and the distorted distribution of the illustrated current responses reflecting the magnetic non-linearity.

FIG. 3 shows a time curve (plot) of voltage u (top graph), resulting flux v (middle graph), and current i (bottom graph), in each case with a d-component (solid line) and a q-component (dashed line) during a macroscopic flux pulse, with additional application of an injection cycle.

FIG. 4 shows an illustration of the calculated anisotropy vectors for all flux pulses of an initial start-up operation. With reference to FIG. 2, each anisotropy vector is plotted by a line that starts from the associated current point, with the length unit of 500 A/Vs having been selected for an illustration of the scaling.

FIG. 5 shows a time curve (plot) of voltage u (top graph), resulting flux ψ (middle graph), and current i (bottom graph), in each case with a d-component (solid line) and a q-component (dashed line) during a macroscopic flux pulse, with additional application of an injection cycle and a subsequent counter pulse for compensation of angular momentum.

### DETAILED DESCRIPTION

Detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of components. Therefore, specific structural and functional details disclosed herein are not to be interpreted as limiting, but merely as a representative basis for teaching one skilled in the art to variously employ the present invention.

The term “admittance Y” of a synchronous machine denotes the inverse of the “inductance L” of the synchronous machine. The admittance Y and the inductance L are both described as a matrix for magnetically anisotropic behavior per the following equation (1):

$${Y}_{s}^{s} = [ \begin{matrix}{Y}_{αα} & {Y}_{αβ} \\ {Y}_{βα} & {Y}_{ββ}\end{matrix} ] = [ \begin{matrix}\frac{\partial {i}_{α}}{\partial {ψ}_{α}} & \frac{\partial {i}_{α}}{\partial {ψ}_{β}} \\ \frac{\partial {i}_{β}}{\partial {ψ}_{α}} & \frac{\partial {i}_{β}}{\partial {ψ}_{β}}\end{matrix} ] = {L}_{s}^{{s}^{- 1}} \qquad ( 1 )$$

The superscript generally stands for the coordinate system (CS), in the present case stator coordinates (α and β axes); the subscript describes the variable (quantity) in greater detail, in the present case the reference to the variable for the stator winding (the relationship between the quantity and the stator winding).

The transformation matrix T(θ) is per the following equation (2):

$$T ( θ ) = [ \begin{matrix}cos θ & - sin θ \\ sin θ & cos θ\end{matrix} ] \qquad ( 2 )$$

The transformation matrix T(θ) allows the conversion of vectors from one coordinate system into another coordinate system, per the following equations (3) and (4):

$$\begin{matrix}{i}_{r}^{s} = T ( - {θ}_{r} ) {i}_{s}^{s} & ( 3 ) \\ {Y}_{s}^{r} = T ( - {θ}_{r} ) {Y}_{s}^{s} T ( {θ}_{r} ) & ( 4 )\end{matrix}$$

In these examples, the current vector and the admittance matrix have been converted from stator coordinates to rotor coordinates (d and q axes) using the rotor angle.

The anisotropy vector y_{Δ}^{s} is the linear combination of the components of the admittance matrix Yₛ^{s} per the following equation (5):

$${y}_{Δ}^{s} = [ \begin{matrix}{y}_{Δ6} \\ {y}_{Δβ}\end{matrix} ] = \frac{1}{2} [ \begin{matrix}{Y}_{αα} - {Y}_{ββ} \\ {Y}_{αβ} + {Y}_{βα}\end{matrix} ] \qquad ( 5 )$$

The anisotropy vector y_{Δ}^{s} may be converted into a fixed-rotor representation by means of the transformation matrix T(θ) using twice the rotor angle per the following equation (6):

$${y}_{Δ}^{r} = [ \begin{matrix}{y}_{Δ d} \\ {y}_{Δ q}\end{matrix} ] = T ( - 2 {θ}_{r} ) {y}_{Δ}^{s} \qquad ( 6 )$$

The fixed-rotor representation of the anisotropy vector Y_{Δ}^{s} has an equivalent relationship with the fixed-rotor admittance matrix per the following equation (7):

$${y}_{Δ}^{r} = \frac{1}{2} [ \begin{matrix}\frac{\partial {i}_{d}}{\partial {ψ}_{d}} - \frac{\partial {i}_{q}}{\partial {ψ}_{q}} \\ \frac{\partial {i}_{d}}{\partial {ψ}_{q}} + \frac{\partial {i}_{q}}{\partial {ψ}_{d}}\end{matrix} ] \qquad ( 7 )$$

In addition, for certain methods the isotropic component Y_{Σ} is also relevant, and may be calculated by a linear combination per the following equation (8):

$${Y}_{Σ} = \frac{1}{2} ( {Y}_{αα} + {Y}_{ββ} ) \qquad ( 8 )$$

The isotropic component Y_{Σ} is not to be assigned to any coordinate system. By combining the anisotropy vector y_{Δ}^{s} and the isotropic component Y_{Σ}, the admittance vector y_{ΔΣ}^{s} is obtained in the corresponding coordinates of the anisotropy vector.

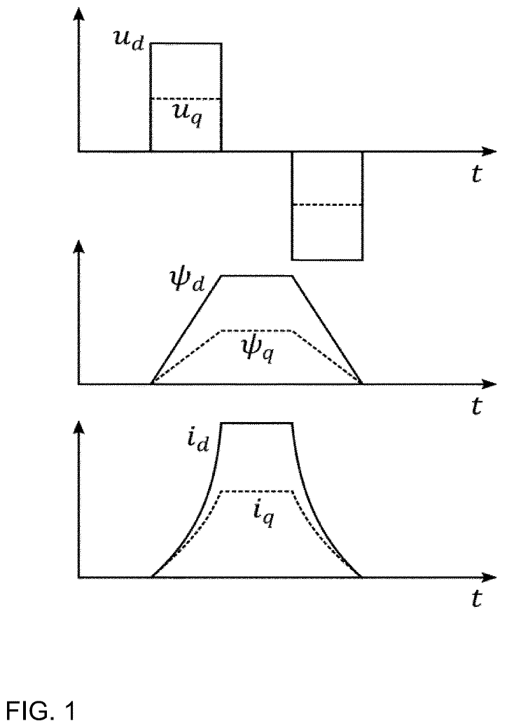

Macroscopic flux pulses are applied (impressed) which allow the motor current to briefly increase into a range (magnitude) that can change the magnetic saturation state of the motor. Each flux pulse is preceded by a setpoint (target) flux value that is taken from a table, for example. This setpoint flux value is implemented by applying a voltage-time area. The current value that results at the end of this voltage-time area is measured and stored. The top graph in FIG. 1 shows how constant voltage values are applied in the d and q directions over a certain time Δt.

The flux ψ is defined according to the general equation (9):

$$ψ = {\int }_{0}^{Δ t} u dt \qquad ( 9 )$$

In the middle graph of FIG. 1, there is a linear flux increase during the constant voltage phases. When a constant voltage value u is selected, the duration Δt for the voltage application is readily calculated according to the following equation (10):

$$Δ t = \frac{ψ}{u} \qquad ( 10 )$$

However, non-constant voltage values or different durations Δt for d-voltage and q-voltage may be used when the voltage-time area according to equation (9) corresponds to the setpoint flux value.

Furthermore, the actual impressed voltage may be adjusted for known disturbance or interference terms (e.g., resistance and/or converter non-linearities) that are not included in the calculation of the voltage-time area. In addition, within the scope of the available intermediate circuit voltage (i.e., DC link voltage), the applied voltage values may preferably be selected to be as high as possible (and the durations Δt selected to be correspondingly short) to minimize these interfering influences.

In the bottom graph of FIG. 1 by way of example, it is apparent how the current increases non-linearly, which may take place differently in the d-component and the q-component. This non-linear increase of the current during a linear flux increase is caused by the magnetic saturation of the iron in the machine and differs qualitatively and quantitatively among different types of motors. For an unambiguous rotor position assignment rule according to bibliography references [1] or [2], it is essential to have data available concerning this non-linear behavior.

Thus, at the end of the voltage-time area, a setpoint flux value is established in the flux, and the non-linear associated current value is established in the current. The current value is detected by a current measurement.

Optionally, as illustrated by way of example in FIG. 1, after the voltage-time area, a small or zero voltage may be temporarily applied to minimize interfering influences during the current measurement (for example, by charge reversal of the motor cable).

The torque M that accompanies the pulse is calculated per the following equation (11):

$$M = {ψ}_{d} {i}_{q} - {ψ}_{q} {i}_{d} \qquad ( 11 )$$

The torque M is converted into angular momentum, resulting in a rotational movement. The rotational movement, after the flux pulse has concluded, must first come to a standstill before a next pulse can be applied.

Thus, as illustrated by way of example in FIG. 1, each flux pulse is terminated with a negated voltage-time area, via which the flux values and the current are quickly brought back to zero. This second voltage-time area in both its d component and q component has the same magnitude as the first voltage-time area, but with a reversed algebraic sign (i.e., the first and second voltage-time areas have opposite signs).

Lastly, the values of the flux pulse and the values of the measured resulting current are assigned to one another and stored as an operating point data pair. The next setpoint flux value is taken from a table, for example, to repeat the operation for a plurality of systematically different flux values. Thus, a plurality of macroscopic flux pulses having various d and q components are applied, and the resulting operating point data pairs are stored in a table.

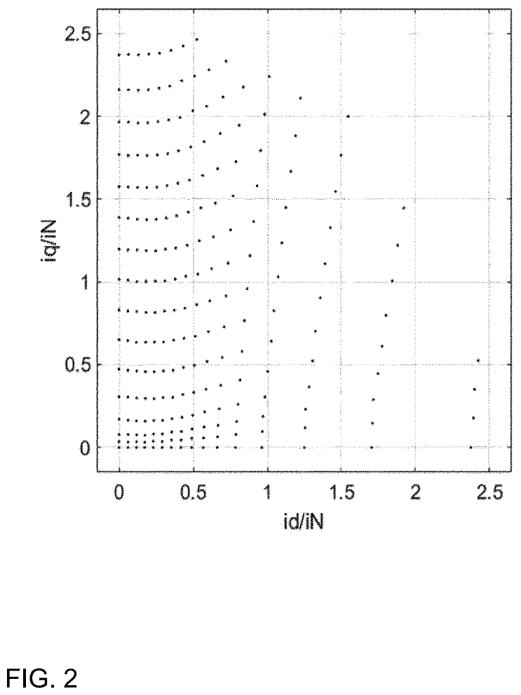

This results in a data set as illustrated by way of example in FIG. 2. The d component and q component of each measured current value are plotted by a point, with 224 flux pulses having been applied. The setpoint flux values lie on a rectangular equidistant grid (with omission of pulses that would have exceeded 250% of the nominal current), while the arrangement of the current points is clearly distorted. This distortion mirrors the magnetic non-linearity of the present motor, which in this example case is a synchronous reluctance motor. The symmetry conditions allow measurement in only one quadrant. Synchronous motors having magnets also require measurements with a negative d current.

In one embodiment, after the current measurement, an injection pattern is run through for each macroscopic flux pulse, i.e., while the macroscopic current value is still present. This injection pattern is made up of microscopic flux pulses, which due to their voltage-time areas which are many times smaller, are not to change the saturation state, but which are suitable for detecting the value of the local inductance or admittance at this operating point. Thus, immediately after the macroscopic flux pulse, multiple microscopic, i.e., non-relevant saturation-changing, flux pulses are applied which are different from one another, add to a sum of zero, and which in their shape and configuration form the injection pattern.

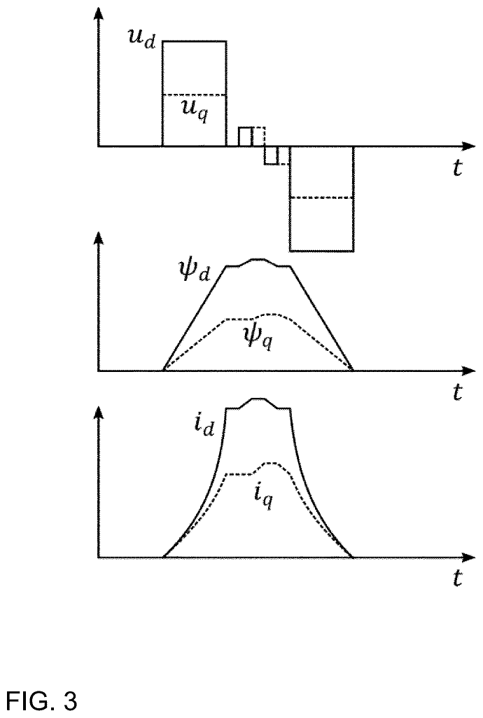

FIG. 3 shows by way of example the application of a square injection pattern, where the microscopic pulses are applied first in the +d direction, then in the +q direction, then in the −d direction, and lastly in the −q direction. The microscopic pulses have the same magnitude and are orthogonal or antiparallel with respect to one another, so that the injection pattern is a square. However, the technical advantages of this injection pattern described in bibliography reference [3] are not essential for this admittance measurement, and any other injection pattern may be used here.

As a result of the microscopic voltage-time areas, small linear flux increases are apparent in the middle graph of FIG. 3, which in turn result in somewhat greater but likewise approximately linear current increases. They are approximately linear because the microscopic injection pulses do not change the saturation state in a relevant manner.

The current response to each of the microscopic pulses is detected and recorded. After conclusion of the injection pattern, all measured values are converted into inductance, admittance, and/or anisotropy values, using the known algorithms of the associated injection behavior, i.e., in this case according to bibliography reference [3], for example. Thus, for example, the dq components of the anisotropy vector y § from equation (6) can be calculated per the following equations (12), (13), and (14):

$$\begin{matrix}{y}_{Δ d} = ( Δ {i}_{d 0} - Δ {i}_{q 1} - Δ {i}_{d 2} + Δ {i}_{q 3} ) / {ψ}_{inj} & ( 12 ) \\ {y}_{Δ q} = ( Δ {i}_{q 0} + Δ {i}_{d 1} - Δ {i}_{q 2} - Δ {i}_{d 3} ) / {ψ}_{inj} & ( 13 ) \\ {y}_{Σ} = ( Δ {i}_{d 0} + Δ {i}_{q 1} - Δ {i}_{d 2} - Δ {i}_{q 3} ) / {ψ}_{inj} & ( 14 )\end{matrix}$$

When the d change in current due to the first microscopic pulse is used for Δi_{d0}, the q current increase due to the second microscopic pulse is used for Δi_{q1}, etc., and ψᵢₙⱼ describes the sum of the voltage-time areas of all microscopic injection flux pulses.

Optionally, microscopic centering pulses may be provided before the first microscopic pulse and after the last microscopic pulse to keep the injection response centered around the macroscopic measured current value. However, here as well it is generally recommended to keep the duration of the injection application as short as possible to minimize the resulting rotational movement.

Lastly, after the inductance, admittance, and/or anisotropy values are calculated, they are assigned to the macroscopic pulse, i.e., to the flux value and/or current value, and stored. This sequence is repeated after each macroscopic flux pulse. Thus, based on the current response to the injection pattern, the entries for the local admittance or inductance are calculated, added to the operating point data pair, and stored.

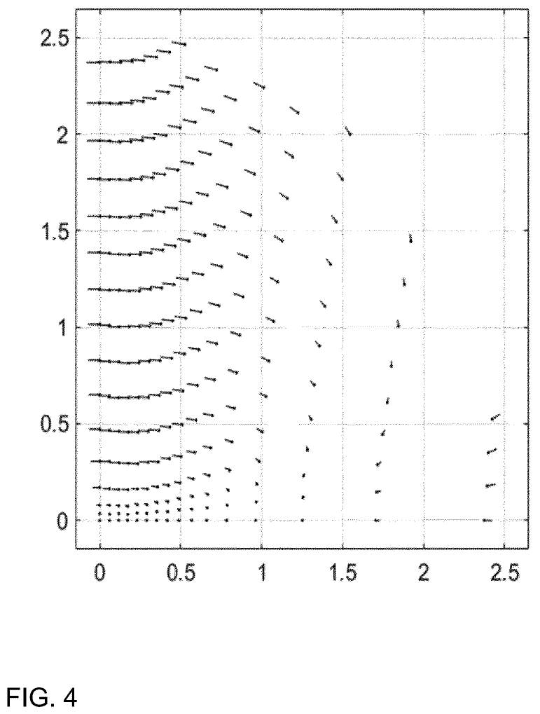

As a result, the data set example from FIG. 2 is expanded by the associated inductance, admittance, and/or anisotropy data. For the example motor, this is illustrated in FIG. 4 by dark solid lines which, starting from the associated current point in the actual direction and the scaled length, depict the respective anisotropy vector y_{Δd} and y_{Δq}.

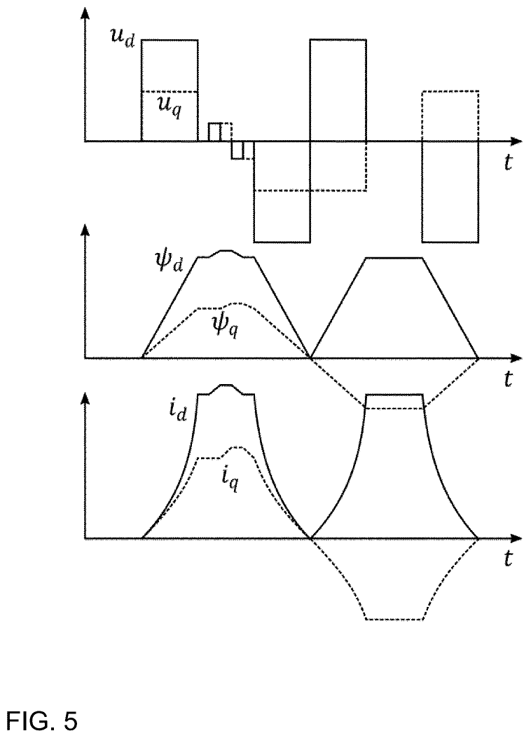

The formation of angular momentum due to the macroscopic pulses may be compensated for by applying a counter pulse immediately after the test pulse, as illustrated by way of example in the right portion of FIG. 5. For this purpose, mirror symmetry of the torque about the d axis is assumed, which is valid for all types of synchronous motors regardless of their specific saturation behavior. Consequently, angular momentum may be compensated for by applying a second pulse which in magnitude and duration is identical to the first pulse, but with the algebraic sign of the q component of all illustrated variables being reversed, while the algebraic sign of the d component remains the same (compare the left and right portions of FIG. 5). Thus, each macroscopic flux pulse is followed by an associated compensation pulse that has the same d component and a negated q component to minimize the resulting angular momentum. There is no need to repeat the injection pattern since it has no mean values.

However, because of various effects (including the influence of the resistance and the slight rotor rotation, among others), for practical purposes the counter pulse usually cannot be generated in (exactly) the same magnitude. As such, some angular momentum remains after the counter pulse is concluded. In addition, even with perfect compensation for angular momentum, the rotational speed at the end would be zero, but the rotor would be skewed relative to its position before the test pulse (starting position). Therefore, prior to the next test pulse the rotor position must be re-determined, and thus the validity of the dq coordinate system (CS) must be restored.

In one embodiment, this is achieved in that, prior to each macroscopic flux pulse, a direct current in the range of the nominal motor current is applied in a defined direction until the resulting oscillating motion has died down and the rotor together with the current is oriented in its starting position. For this purpose, the dq coordinate system during the rotor movement does not co-rotate with the rotor; instead, it is initialized only once before the first test pulse, and from then on remains fixedly aligned with the starting position for the duration of all test pulses. In these fixed dq coordinates, following a test pulse, a d current may be easily adjusted and a parameterizable time may be awaited. By specifying the q current proportionally to the q voltage in these fixed dq coordinates, an additional damping term may optionally be provided which allows the oscillating motion to die down more quickly. The initialization of the dq coordinate system prior to the first test pulse may take place via sensor-less initial position determination (according to bibliography reference [4], for example) to minimize the rotor movement due to the application of the first direct current or may also take place as desired if the rotor movement is not relevant.

In another embodiment, the motor shaft is externally mechanically blocked prior to the first test pulse, so that the mechanical rigidity brings the rotor back into its starting position after each pulse, and an application of direct current is not necessary. However, in this case a sensor-less initial position determination (according to bibliography reference [4], for example) is necessary at the beginning to reliably align the dq coordinate system with the blocked rotor.

In another embodiment, after each test pulse and dying-down process of the movement, a new sensor-less initial position recognition is carried out, and the dq coordinate system for the subsequent pulse is realigned. Even though the accuracy of the sensor-less initial position recognition is generally lower than that of an alignment by application of direct current, this embodiment may be advantageous if a sufficiently good direct current alignment is not possible, for example due to special circumstances such as strong friction or a high reluctance component in the nominal torque of a permanent magnet motor.

After all data pairs of the flux and the current (see FIG. 2) and optionally the admittance (see FIG. 4) are stored, the derivation of the position assignment parameters is lastly carried out. As a basis for such, a rule for value calculation far from/between/outside the data pairs is selected. This may be a linear or non-linear interpolation/extrapolation, acquisition of the next value, an analytical or numerical approximation, or some other type of smoothing rule. Regardless of the choice for this rule, the term “interpolation” is used below for the selected rule.

In one embodiment, simple rotor position assignment parameters are calculated by interpolation, using the entries in the table. For this purpose, the load dependency of the secant inductance and of the anisotropy shift, for example, which are examples of parameters for simple sensor-less methods, is determined. For this purpose, initially a current trajectory that is to be used during operation is selected (for example, the maximum torque per ampere (MTPA) curve). Multiple current points are subsequently taken from this trajectory, and for each of these points iₛ^{r} the value of the flux ψₛ^{r} and optionally the value of the anisotropy y_{Δ}^{r} are interpolated over the stored data pairs.

On this basis, for each of these points, the value of the secant inductance L_{q}, for example, is calculated per the following equation (15):

$${L}_{q} = {ψ}_{q} / {i}_{q} \qquad ( 15 )$$

The value of the anisotropy shift θₐ is calculated per the following equation (16):

$${θ}_{a} = \frac{1}{2} atan ( \frac{{y}_{Δ q}}{{y}_{Δ d}} ) \qquad ( 16 )$$

The values of the secant inductance L_{q} and the anisotropy shift θₐ are assigned to the selected current point and stored. This results in a table of these parameters along the setpoint current trajectory, by means of which the load-dependent value of the respective parameter may then be interpolated during subsequent operation. Other parameters may also be interpolated, analogously to equations (15) or (16), that are directly correlated with the flux or the admittance, when these are required by an operational process.

In another embodiment, unambiguous rotor position assignment parameters are derived from the entries in the table by interpolation and SFC (stator-frame fixed electric current) calculation. For this purpose, so-called SFC trajectories of the flux and/or the admittance, which are the basis for unambiguous position assignment methods in bibliography references [1] and [2], are derived from the stored data pairs. According to bibliography references [1] and [2], these SFC trajectories describe the profile of the flux or the admittance over the variable rotor position when the current is kept in stator coordinates. Any given fixed current in stator coordinates is results in the following rotor position-dependent value if in rotor coordinates per the following equation (17):

$${i}_{s}^{r} ( {θ}_{r} , {i}_{s}^{s} ) = T ( - {θ}_{r} ) {i}_{s}^{s} \qquad ( 17 )$$

By use of this rotor position-dependent current in rotor coordinates iₛ^{r}(σᵣ, iₛ^{s}), an interpolation is now carried out over the stored data pairs to obtain a rotor position-dependent flux ψₛ^{r}(θᵣ, iₛ^{s}), a position-dependent admittance y_{Δ}^{r}(θᵣ, iₛ^{s}) or a y_{ΔΣ}^{r}(θᵣ, iₛ^{s}). The value of the position-dependent admittance y_{ΔΣ}^{r}(θᵣ, iₛ^{s}) is obtained per the following equation (18):

$${y}_{ΔΣ}^{r} ( {θ}_{r} , {i}_{s}^{s} ) = [ \begin{matrix}{y}_{Δ}^{r} ( {θ}_{r} , {i}_{s}^{s} ) \\ {Y}_{Σ} ( {θ}_{r} , {i}_{s}^{s} )\end{matrix} ] \qquad ( 18 )$$

These interpolated values are subsequently transformed back to stator coordinates to obtain as the result the SFC trajectories of the flux ψₛ^{s}(θᵣ, iₛ^{s}) and the admittance y_{Δ}^{s}(θᵣ, iₛ^{s}) or y_{ΔΣ}^{s}(θᵣ, iₛ^{s}) per the following equations (19), (20, and (21):

$$\begin{matrix}{Ψ}_{s}^{s} = ( {θ}_{r} , {i}_{s}^{s} ) = T ( {θ}_{r} ) ( {ψ}_{s}^{r} ( {θ}_{r} , {i}_{s}^{s} ) + [ \begin{matrix}{ψ}_{pm} \\ 0\end{matrix} ] ) & ( 19 ) \\ {y}_{Δ}^{s} ( {θ}_{r} , {i}_{s}^{s} ) = T ( 2 {θ}_{r} ) {y}_{Δ}^{r} ( {θ}_{r} , {i}_{s}^{s} ) & ( 20 ) \\ {y}_{ΔΣ}^{s} ( {θ}_{r} , {i}_{s}^{s} ) = [ \begin{matrix}{y}_{Δ}^{s} ( {θ}_{r} , {i}_{s}^{s} ) \\ {Y}_{Σ} ( {θ}_{r} , {i}_{s}^{s} )\end{matrix} ] & ( 21 )\end{matrix}$$

In equation (19), the magnetic flux linkage is added to the remanence component ψₚₘ, so that Ψₛ^{s} is now a complete magnetic flux linkage, while all preceding flux values ψ, by definition, are free of remanence, and for zero current were therefore zero.

These SFC trajectories ψₛ^{s}(θᵣ, iₛ^{s}) and y_{Δ}^{s}(θᵣ, iₛ^{s}) or y_{ΔΣ}^{s}(θᵣ, iₛ^{s}) are the basis for deriving an unambiguous rotor position assignment, which is then specifically carried out according to bibliography references [1] or [2].

### BIBLIOGRAPHY

[1] P. Landsmann, D. Paulus, and S. Kühl, “Method and device for controlling a synchronous motor without position sensors by unambiguous assignment of the admittance or inductance to the rotor position”, German published patent application DE 10 2018 006 657 A1, Aug. 17, 2018 (corresponds to U.S. Pat. No. 11,456,687).
[2] P. Landsmann, D. Paulus, and S. Kühl, “Method and device for controlling a synchronous machine without position sensors by unambiguous assignment of the flux linkage to the rotor position”, European published patent application EP 3 826 169 A1, Nov. 25, 2019 (corresponds to U.S. Pat. No. 11,722,082).
[3] P. Landsmann, “Method for identifying the magnetic anisotropy of an electric induction machine”, German published patent application DE 10 2015 217 986 A1, Sep. 18, 2015.
[4] J. Holtz, “Initial Rotor Polarity Detection and Sensorless Control of PM Synchronous Machines,” Conference Record of the 2006 IEEE Industry Applications Conference, Forty-First IAS Annual Meeting, Oct. 8, 2006.

While exemplary embodiments are described above, it is not intended that these embodiments describe all possible forms of the present invention. Rather, the words used in the specification are words of description rather than limitation, and it is understood that various changes may be made without departing from the spirit and scope of the present invention. Additionally, the features of various implementing embodiments may be combined to form further embodiments of the present invention.

What is claimed is:

1. A method for measuring magnetic saturation profiles of a synchronous machine having a rotor and a stator, the method comprising:
actuating the synchronous machine with clocked terminal voltages according to a pulse width modulation process;
cyclically measuring a current of the synchronous machine resulting from the synchronous machine being actuated by the clocked terminal voltages; and
applying macroscopic flux pulses which allow the current to momentarily increase into a range that can change a magnetic saturation state of the synchronous machine.

2. The method of claim 1 further comprising:
assigning values of the macroscopic flux pulse and of the measured resulting current to one another as an operating point data pair and storing the operating point data pair in a table.

3. The method of claim 1 further comprising:
immediately after each macroscopic flux pulse, applying multiple microscopic flux pulses which are different from one another, have a sum of zero, and which in their shape and configuration form an injection pattern, wherein the magnetic saturation state of the synchronous machine remains unchanged after the microscopic flux pulses have been applied.

4. The method of claim 3 wherein:
the microscopic flux pulses all have the same magnitude and are all orthogonal or antiparallel with respect to one another so that the injection pattern is a square.

5. The method of claim 3 further comprising:
calculating local admittance or inductance entries based on the current response to the injection pattern; and
storing the calculated local admittance or inductance entries in a table.

6. The method of claim 2 further comprising:
applying a plurality of macroscopic flux pulses having various d and q components; and
storing resulting operating point data pairs in the table.

7. The method of claim 1 further comprising:
applying, after each of the macroscopic flux pulses, an associated compensation pulse that has the same d component and a negated q component to minimize resulting angular momentum.

8. The method of claim 1 further comprising:
applying, prior to each macroscopic flux pulse, a direct current in the range of nominal current in a defined direction until a resulting oscillating motion has died down and the rotor is aligned with the current.

9. The method of claim 2 further comprising:
calculating rotor position assignment parameters by interpolation, using operating point data pair entries in the table.

10. The method of claim 2 further comprising:
deriving unambiguous rotor position assignment parameters from operating point data pair entries in the table by interpolation.

11. A device for open-loop and closed-loop control of an induction machine having a stator and a rotor, the device comprising:
a controllable pulse width modulation (PWM) converter for outputting clocked terminal voltages;
an apparatus for detecting current; and
a controller configured to control the PWM converter to actuate the induction machine with the clocked terminal voltages, control the apparatus to cyclically measure a current of the induction machine resulting from the induction machine being actuated by the clocked terminal voltages, and apply macroscopic flux pulses which allow the current to momentarily increase into a range that can change a magnetic saturation state of the induction machine.

12. A synchronous machine comprising a stator, a rotor with or without permanent magnets, and the device of claim 11.
